(19) United States
(12) Patent Application Publication
(10) Pub. No.: US 2020/0318993 A1
(43) Pub. Date: Oct. 8, 2020

(54) ROTATIONAL POSITION SENSOR WITH TUNNEL MAGNETORESISTIVE SENSOR

(71) Applicants: THYSSENKRUPP PRESTA AG, Eschen (LI); thyssenkrupp AG, Essen (DE)

(72) Inventors: Zoltán BARANYAI, Herceghalom (HU); Ábel VÉR, Budapest (HU)

(73) Assignees: THYSSENKRUPP PRESTA AG, Eschen (LI); thyssenkrupp AG, Essen (DE)

(21) Appl. No.: 16/305,243

(22) PCT Filed: Jul. 1, 2016
(86) PCT No.: PCT/EP2016/065591

§ 371 Date: Nov. 28, 2018

(51) Int. Cl. G01D 3/08; G01D 5/14; H02K 11/215; G01R 33/09; B62D 5/04

(52) U.S. Cl. CPC G01D 3/08; G01D 5/145; B62D 5/04; G01R 33/098; H02K 11/215

(57) ABSTRACT

A rotor position sensor for an electric motor of an electric power steering apparatus for assisting steering of a motor vehicle is configured to generate a sensor signal which represents the rotor position of the electric motor's rotor. The rotor position sensor has at least one sensor unit that generates electrical signals having different phases in accordance with rotation of a rotary shaft of the electric motor that is a sensing target, wherein the rotor position sensor includes two redundant sensor units wherein each of the sensor units includes tunnel magnetoresistive elements.

### CROSS REFERENCE TO RELATED APPLICATION

This application is a U.S. National Stage Entry of International Patent Application Serial Number PCT/EP2016/065591, filed Jul. 1, 2016, the entire contents of which are incorporated herein by reference.

### FIELD

The present disclosure generally relates to a rotor position sensor for an electric power steering apparatus for assisting steering of a motor vehicle.

### BACKGROUND

An electric power steering apparatus is designed to supply a steering assist torque from an electric motor to a steering mechanism to decrease the load on the driver while steering the motor vehicle.

In recent years, in electric power steering systems brushless DC motors have come to be used. In a brushless DC motor, since a current caused to pass through a stator is PWM (Pulse Width Modulation) controlled so as to generate a rotating magnetic field according to a rotational position of a rotor, a detector is incorporated for detecting a rotor position.

In order to ensure reliability of the rotational angle detection of the motor's rotor shaft, multiple angle sensors are used. When a failure occurs in one sensor, the other sensor can still detect the position of the motor's rotor shaft to continue position measurement.

EP 2 752 645 A2 discloses a method for providing an abnormality detection for a rotor angle sensor. A control circuit identifies an abnormality in the sine and cosine signals in order to execute a backup control on the motor. The abnormality detection is based on a correlation between the ambient temperature of the magnetic sensor and the amplitude of the electrical signals.

Thus a need exists for an electric power steering apparatus with a rotation angle sensor having improved capability of detecting an abnormality of a magnetic sensor and in case of abnormality the sensor being able to continue measuring the rotation angle with high precision.

### BRIEF DESCRIPTION OF THE FIGURES

FIG. 1 is a schematic view of an electric power steering apparatus.

FIG. 2 is a block diagram showing an electrical structure of the electric power steering apparatus.

FIG. 3 is a schematic view of a sensor unit of the rotor position sensor.

FIG. 4 is a block diagram of the rotor position sensor.

### DETAILED DESCRIPTION

Although certain example methods and apparatus have been described herein, the scope of coverage of this patent is not limited thereto. On the contrary, this patent covers all methods, apparatus, and articles of manufacture fairly falling within the scope of the appended claims either literally or under the doctrine of equivalents. Moreover, those having ordinary skill in the art will understand that reciting “a” element or “an” element in the appended claims does not restrict those claims to articles, apparatuses, systems, methods, or the like having only one of that element, even where other elements in the same claim or different claims are preceded by “at least one” or similar language. Similarly, it should be understood that the steps of any method claims need not necessarily be performed in the order in which they are recited, unless so required by the context of the claims. In addition, all references to one skilled in the art shall be understood to refer to one having ordinary skill in the art.

The present invention relates to a rotor position sensor for an electric power steering apparatus for assisting steering of a motor vehicle according to the claims.

Accordingly, a rotor position sensor for an electric motor of an electric power steering apparatus for assisting steering of a motor vehicle which is designed to generate a sensor signal which represents the rotor position of the electric motor's rotor is provided, wherein the rotor position sensor has at least one angle sensor unit, that generates electrical signals having different phases in accordance with rotation of a rotary shaft of the electric motor that is a sensing target, wherein the rotor position sensor comprises two redundant angle sensor units, wherein each of the sensor unit comprises tunnel magnetoresistive elements. Preferably the angle sensor unit comprises four tunnel magnetoresistive elements. With this redundant configuration of the rotor position sensor it is always possible to calculate the correct rotor position from the electrical signals. The failure time is minimized because the rotor position sensor provides a failure tolerant system. A failure mode can be directly detected and the root cause of the error can be identified, making it possible to keep the full functionality of the sensor with the same safety level.

Preferably the angle sensor unit is formed as the magnetoresistive sensor unit. It could also be formed as a tunnel hall sensor unit.

Preferably, for each of the magnetoresistive sensor units the four electrical signals include positive and negative sine signals having a phase difference of 180° and positive and negative cosine signals having a phase difference of 180°.

It is favoured that the rotor position sensor has a microcomputer that is designed to compute a rotation angle of the rotary shaft based on the electrical signals generated by the two magnetoresistive sensor units.

It is further favoured that the microcomputer is designed to detect an abnormality in the electrical signals. If an abnormality is detected in one of the two sensor units, it is preferred that the microcomputer is designed to calculate the rotation angle based on the electrical signals generated by the other sensor unit. The microcomputer can be designed to detect an abnormality in the electrical signals by comparison of the signals between the two redundantly working magnetoresistive sensor units and/or the microcomputer can be designed to detect the abnormality in the electrical signals by comparison of the electrical signals independently of the respective magnetoresistive sensor unit. With the usage of the sine and cosine and the inverted signal pairs in total four calculated angle signals can be compared for error detection.

In a preferred embodiment each magnetoresistive sensor unit comprises a first bridge circuit and a second bridge circuit. In a preferred embodiment the magnetoresistive sensor unit comprises a third bridge circuit and a fourth bridge circuit. With the usage of further bridge circuits more faults are tolerable while a rotation angle of the rotary shaft can still be computed.

Preferably, the second bridge circuit is disposed so as to be offset from the first bridge circuit by a prescribed angle of 45° or 90° in the rotation direction of the rotary shaft. Even more preferably, the first and second bridge circuits are each formed of a first half bridge circuit in which two tunnel magnetoresistive elements are connected in series, and a second half bridge circuit in which two tunnel magnetoresistive elements are connected in series, wherein the first ends of the two half bridge circuits are connected to the power source and the second ends of the two half bridge circuits are grounded.

It is advantageous, if the magnetoresistive sensor units are arranged to have an offset angle of 45° in the rotation direction of the rotary shaft.

Preferably, the two magnetoresistive sensor units including the first and second bridge circuits, respectively, are arranged in a concentric manner on the same sensor substrate.

Further an electric power steering apparatus for assisting steering of a motor vehicle by conferring torque generated by an electric motor to a steering mechanism by a rotation of a rotor of the motor in relation to a stator is provided, the apparatus comprising a rotor position sensor as described above, wherein the rotor position sensor redundantly measures the rotor position of the electric motor's rotor.

A preferred embodiment of the present invention will be described with reference to the drawings. In all figures the same reference signs denote the same components or functionally similar components.

FIG. 1 is a schematic diagram of an electric power steering apparatus 1. A steering wheel 2 is fixed to a upper steering shaft 3, the steering movement of the driver is transmitted via a torsion bar to a lower steering shaft 3′. The lower steering shaft 3′ is coupled to a rack 4 via a rack-and-pinion mechanism 5. Rotation of the higher and lower steering shafts 3, 3′ accompanying a steering operation is converted into a reciprocating linear motion of the toothed rack 4 by the rack-and-pinion mechanism 5. The linear motion of the rack 4 changes the steering angle of the steered road wheels 6. To provide steering assistance, in a preferred embodiment an electric motor 7 is mounted to the side of the rack housing and drives a ball-screw mechanism 8 via a toothed rubber belt 9. The invention is also applicable for other methods of transferring the motor torque into the steering mechanism. Electric power assist is provided through a steering controller (ECU) 10 and a power assist actuator 11 comprising the electric motor 7 and a motor controller 12. The steering controller 10 receives signals representative of the vehicle velocity v and the torque T_{TS} applied to the steering wheel 2 by the vehicle operator. In response to the vehicle velocity v and the operator torque T_{TS}, the controller 10 determines the target motor torque T_{d} and provides the signal through to the motor controller 12, where the duty cycles are calculated to produce the phase currents via PWM (pulse-width modulation).

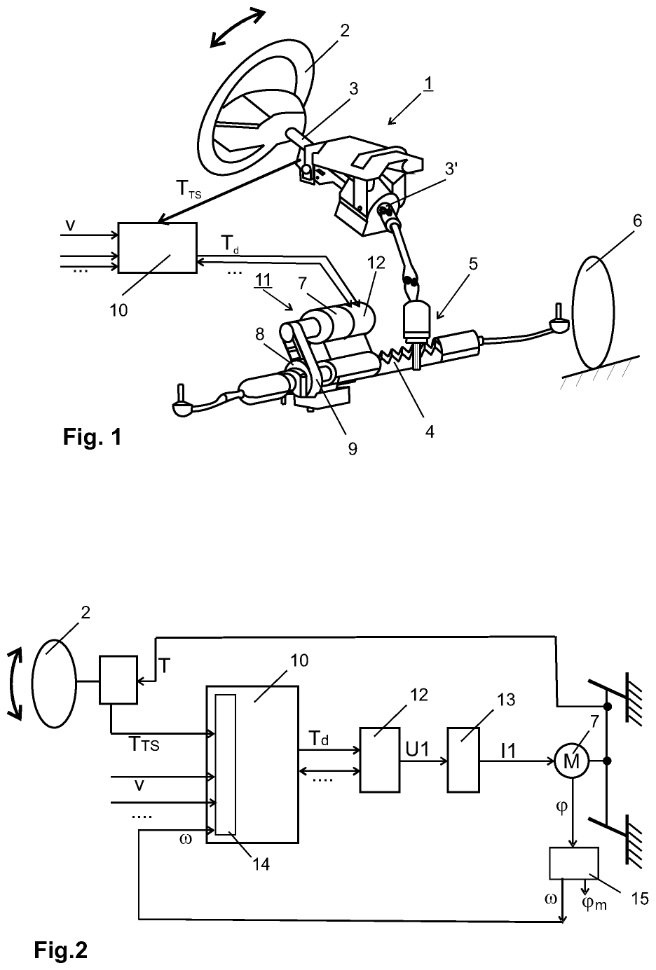

FIG. 2 shows a block diagram of the electrical structure of the electric power steering apparatus 1. The steering controller 10 receives signals representative of the vehicle velocity v, the torque T_{TS} applied to the steering wheel 2 by the vehicle operator and the electrical angular frequency ω of the rotor of the motor 7 and derives the target motor torque T_{d}. This torque is fed to the motor controller 12 which determines the voltage input U1 for the PWM and a motor driver 13 generates via the PWM the motor currents I1=i_{U}, i_{V}, i_{W}. The electric motor 7 has a rotor position sensor 15, wherein the rotor position sensor is designed to generate a sensor signal which represents the rotation angle φ. From the rotation angle φ the angular frequency ω is calculated in a microcomputer 14.

The rotor position sensor includes a bias magnet and a tunnel magnetoresistive element (TMR) that is a magnetic sensor. The bias magnet is fixed to an end of the motor's rotary shaft. The TMR sensor faces the bias magnet in a direction along the axis of the rotary shaft. The basic layered structures of TMR consist of two or more magnetic layers preferably of a Fe—Co—Ni alloy separated by a very thin isolating layer. One layer of the TMR is a “pinned layer” that is not affected by the magnetic field and the other is a “free layer” which has a magnetization that aligns parallel to the applied magnetic field. Electrons can surpass this thin film by means of the quantum tunnel effect, and the crossing probability is higher when both magnetic moments are aligned in parallel and lower when both magnetic moments are not aligned in parallel. So a TMR sensor usually makes use of the spin-valve principle.

The rotor position sensor 15 generates electrical signals corresponding to a rotation angle φ of the rotary shaft. The bias magnet is a columnar bipolar magnet in which a north pole and a south pole are formed so as to be adjacent to each other in the circumferential direction. A bias magnetic field in the direction from the north pole toward the south pole is applied to the TMR sensor by the bias magnet. The direction of the magnetic field applied to the TMR sensor varies depending on the rotation angle φ of the rotary shaft.

The rotor position sensor 15 includes a first angle sensor unit 16 and a second angle sensor unit 16′ each having a first bridge circuit 17, 17′ and a second bridge circuit 18, 18′. The two sensor units 16,16′ work redundantly. Each is connected to the source voltage VDD and to ground GND. The tunnel magnetoresistive elements output electrical signals to the microcomputer 14. The microcomputer 14 determines whether both bridges 17, 17′, 18, 18′ work correct. If a failure occurs in one of the sensor units 16,16′ the microcomputer 14 continues the determination of the rotor position with the output of the other sensor unit.

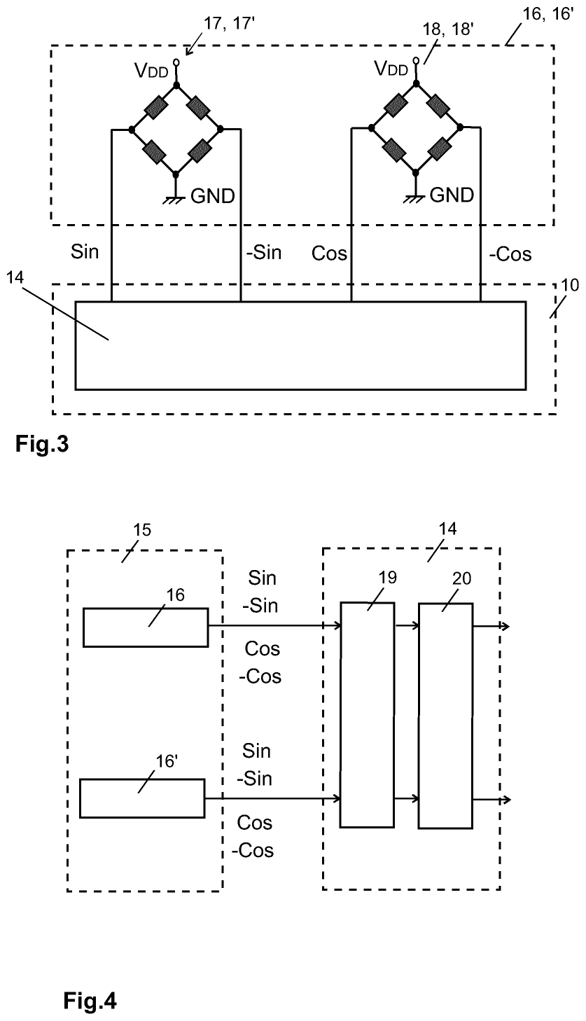

FIG. 3 shows the design of a sensor unit 16,16′. The first and the second bridge circuit 17, 17′, 18, 18′ have a configuration in which four tunnel magnetoresistive elements are arranged in a bridge form.

The first bridge circuit 17, 17′ is formed of a half bridge circuit in which two tunnel magnetoresistive elements out of the four tunnel magnetoresistive elements are connected in series, and a half bridge circuit in which the other two tunnel magnetoresistive elements are connected in series. First ends of the two half bridge circuits are connected to a power source (source voltage+VDD). Second ends of the two half bridge circuits are grounded (GND). The first bridge circuit 17, 17′ outputs a potential at the middle point between the two tunnel magnetoresistive elements as a first electrical signal, and outputs a potential at the middle point between the two tunnel magnetoresistive elements as a second electrical signal.

When the bias magnet rotates together with the rotary shaft and the direction of the bias magnetic field applied to the four tunnel magnetoresistive elements varies, the resistance values of the tunnel magnetoresistive elements vary depending on the variation of the direction of the bias magnetic field. As the resistance values of the tunnel magnetoresistive elements vary, the first and second electrical signals vary. That is, the first and second electrical signals vary depending on the rotation angle φ of the rotary shaft.

The first electrical signal is a sine signal with an amplitude A, which varies sinusoidally with respect to the rotation angle φ of the rotary shaft. The second electrical signal is a −sine signal with an amplitude A, of which the phase is different by 180° from that of the first electrical signal.

The second bridge circuit 18, 18′ has the same circuit configuration as that of the first bridge circuit 17, 17′. The second bridge circuit 18, 18′ is formed of a half bridge circuit in which two tunnel magnetoresistive elements are connected in series, and a half bridge circuit in which two tunnel magnetoresistive elements are connected in series. First ends of the two half bridge circuits are connected to the power source. Second ends of the two half bridge circuits are grounded. The second bridge circuit outputs a potential at the middle point between the two tunnel magnetoresistive elements as a third electrical signal, and outputs a potential at the middle point between the two tunnel magnetoresistive elements as a fourth electrical signal.

The second bridge circuit 18, 18′ is disposed so as to be offset from the first bridge circuit 17, 17′ by a prescribed angle of 90° in the rotation direction of the rotary shaft. Thus, the third electrical signal is a cosine signal with an amplitude A, of which the phase is retarded by 90° with respect to that of the first electrical signal. The fourth electrical signal is a −cosine signal with an amplitude A, of which the phase is different by 180° from that of the third electrical signal.

As shown in FIG. 4 the microcomputer 14 acquires the electrical signals output from the first and second sensor unit 16, 16′ with a prescribed sampling period. The microcomputer 14 computes in a first step 19 a sine and cosine signal for each sensor unit 16, 16′. From the four signals it is possible to detect an abnormal signal. If an abnormal signal is detected the faulty sensor unit signals are discarded and the remaining sensor unit is used to calculate the rotation angle in a second step 20.

The angle sensor unit generate different signals which correspond to sine and cosine output signals of the sensor.

Y corresponds to the Y-axis of the unit circle and X corresponds to the X-axis of the unit circle. The rotor angle calculation takes into account the offset Oₓ O_{y} of the signals in X and Y direction and the errors of the phase β and the amplitude.

The rotor angle is calculated as follows

$$ϕ = arctan ( \frac{Y 3}{X 2} ) - {β}_{X}$$

Wherein Y3 describes the influence of the non-orthogonality of the signals which can be compensated by using

$$Y 3 = \frac{Y 2 - X 2 * sin ( - β )}{cos ( - β )} ,$$

wherein the amplitude correction X2 and Y2 is calculated by using the mean values determined in the calibration and are determined as follows

$$X 2 = \frac{X 1}{A x m}$$

$$and$$

$$Y 2 = \frac{Y 1}{A y m}$$

wherein the offset correction X1, and Y1 is calculated as follows

X2=X−Oₓ

Y1=Y−O_{y},

wherein Oₓ describe the offset of the signals in X-direction, and O_{y} the offset of the signals in Y-direction. Further, X and Y are given by:

$$X = Axm * cos ( α + {β}_{X} ) + {O}_{X}$$

$$y = Aym * sin ( α + {β}_{Y} ) + {O}_{Y}$$

$$α = arctan ( \frac{Y}{X} ) ,$$

wherein α is the ideal rotation angle in °, so in other words it is the erroneous angle failure, wherein Axm is the mean parameter of the amplitude of X, Aym is the mean parameter of the amplitude of Y, βₓ is the phase of X signal, β_{y} is the phase of Y signal.

It may be beneficial for the TMR sensor 15 to have some offset angle between the two redundant sensor units 16, 16′, preferably 45°. In a preferred embodiment of the present invention each bridge leg is handled independently, providing even better fault tolerances with eight signals from two units.

The present invention provides direct diagnostics based on the bridge resistor abnormality with a simple rotor angle calculation.

1.-13. (canceled)

14. A rotor position sensor for an electric motor of an electric power steering apparatus for assisting steering of a motor vehicle configured to generate a sensor signal that represents the rotor position of the electric motor's rotor, wherein the rotor position sensor comprises:
two redundant angle sensor units configured to generate electrical signals having different phases in accordance with rotation of a rotary shaft of the electric motor that is a sensing target,
wherein each of the angle sensor units comprises tunnel magnetoresistive elements.

15. The rotor position sensor of claim 14, wherein the electrical signals from each of the angle sensor units include positive and negative sine signals having a phase difference of 180° and positive and negative cosine signals having a phase difference of 180°.

16. The rotor position sensor of claim 14, wherein the rotor position sensor has a microcomputer that is configured to compute a rotation angle of the rotary shaft based on the electrical signals generated by the angle sensor units.

17. The rotor position sensor of claim 16, wherein the microcomputer is further designed to detect an abnormality in the electrical signals.

18. The rotor position sensor of claim 17, wherein the microcomputer is further designed to calculate the rotation angle based on the electrical signals generated by one of the angle sensor units if an abnormal signal is detected in the other of the angle sensor units.

19. The rotor position sensor of claim 17, wherein the microcomputer is designed to detect the abnormality in the electrical signals by comparison of the signals between the angle sensor units.

20. The rotor position sensor of claim 17, wherein the microcomputer is designed to detect the abnormality in the electrical signals by comparison of the electrical signals independently of respective angle sensor units.

21. The rotor position sensor of claim 14, wherein each of the sensor units comprises a first bridge circuit and a second bridge circuit.

22. The rotor position sensor of claim 21, wherein the second bridge circuit is disposed so as to be offset from the first bridge circuit by a prescribed angle of 45° in the rotation direction of the rotary shaft.

23. The rotor position sensor of claim 21, wherein the first and second bridge circuits are formed each of a first half bridge circuit in which two tunnel magnetoresistive elements are connected in series, and a second half bridge circuit in which two tunnel magnetoresistive elements are connected in series, wherein the first ends of the two half bridge circuits are connected to a power source and the second ends of the two half bridge circuits are grounded.

24. The rotor position sensor of claim 14, wherein the angle sensor units are arranged to have an offset angle of 45° in the rotation direction of the rotary shaft.

25. The rotor position sensor of claim 21, wherein the two sensor units including the first and second bridge circuits, respectively, are arranged in a concentric manner on a same sensor substrate.

26. An electric power steering apparatus for assisting steering of a motor vehicle by conferring torque generated by an electric motor to a steering mechanism by a rotation of a rotor of the motor in relation to a stator, the apparatus comprising a rotor position sensor according to claim 14, wherein the rotor position sensor is able to redundantly measure the rotor position of the rotor of the electric motor.
